(19) United States
(12) Patent Application Publication
(10) Pub. No.: US 2017/0141162 A1
(43) Pub. Date: May 18, 2017

(54) DISPLAY PANEL AND APPARATUS INCLUDING THE SAME

(71) Applicant: INDUSTRY-ACADEMIC COOPERATION FOUNDATION YONSEI UNIVERSITY, Seoul (KR)

(72) Inventors: Young Joo KIM, Goyang-si (KR); Hyo-Jun KIM, Seoul (KR); Min-Ho SHIN, Gimcheon-si (KR); Hyun-Guk HONG, Tongyeong-si (KR)

(21) Appl. No.: 15/351,798

(22) Filed: Nov. 15, 2016

(30) Foreign Application Priority Data
Nov. 16, 2015 (KR) 10-2015-0160642

(51) Int. Cl. H01L 27/32; H01L 51/56; H01L 51/52

(52) U.S. Cl. CPC H01L 27/322; H01L 51/5281; H01L 51/5265; H01L 27/3211; H01L 51/56; H01L 51/5253; H01L 2251/5369

(57) ABSTRACT

A display panel for simplifying a manufacturing process and having high energy efficiency using an OLED as a light source and also using RGB, QDs, and an LPR layer capable of improving color reproducibility. In an aspect, an LPR layer is interposed between a color filter layer and a fluorescent substance layer so that light is circulated within the fluorescent substance layer again. Accordingly, there is provided a display panel capable of reducing the amount of light absorbed through the color filler by increasing the light absorption coefficient of the fluorescent substance layer and of maximizing energy efficiency by increasing the intensity of light passing through the color filter.

### CROSS REFERENCE TO RELATED APPLICATION

The present application claims the benefit of Korean Patent Application No. 10-2015-0160642 filed in the Korean Intellectual Property Office on Nov. 16, 2015, the entire contents of which are incorporated herein by reference.

### BACKGROUND OF THE INVENTION

1. Technical Field

An aspect of the present invention relates to a display panel and, more particularly, a display panel having both improved color reproducibility and high energy efficiency using an OLED as a light source and also using red/green QDs and au LPR layer.

2. Description of the Related Art

Contents described in this part merely provide the background of embodiments of the present invention and do not constitute a conventional technology.

A technology for a display device is advanced daily. As the technologies of a liquid display device (LCD), a light-emitting diode (LED) and an organic light-emitting diode (OLED) satisfy necessary conditions, such as low consumption power, thinness, light weight and high picture quality, the importance of the display device as a visual information transfer medium is highlighted.

As a blue LED is commercialized, an LED electronic display is also capable of a full color implementation and has greatly reduced in price. The OLED is preferred. The reason for this is that the OLED has advantages in that it is vivid even at a bright place because it is self-light emission and that it can have the same color regardless of the direction because it generates the same light in all directions.

Red, green and blue organic light-emitting diodes (RGB OLEDs) according to a conventional technology are very excellent in color reproducibility, but have a difficulty in the process in order to fabricate the OLEDs in a large-area substrate because an OLED has to be patterned for each pixel.

In order to solve such a problem, a display panel in which a white OLED (W-OLED) having a simple manufacturing process is used as backlight and RGB values are implemented using color filters has been researched and developed. However, such a display panel has a problem in that energy consumption is great because it selectively uses only part of light emitted from a large-area white OLED through a color filter and discards the remaining light by absorbing it. For example, the color filter transmits only light of an R wavelength range in order to implement an R region and discards light of the remaining G and B wavelength ranges by absorbing it. Accordingly, energy consumption that much is problematic.

In order to minimize such energy consumption, an attempt is made to form a fluorescent substance layer between a color filter layer and backlight in order to improve energy efficiency by converting light absorbed by the color filter layer into light transmitted by the color filter layer. For example, a method for increasing the intensity of light of an R wavelength range in the R region of the color filter by converting light of G and B wavelength range into the light of the R wavelength range using a fluorescent substance, such as quantum dots, is used. This method is problematic in that practical use is not high because an absorption coefficient in which the fluorescent substance absorbs light is not high.

### SUMMARY OF THE INVENTION

Accordingly, an aspect of the present invention has been made keeping in mind the above problems occurring in the prior art, and an object of the present invention is to provide a display panel, which is capable of reducing the amount of light absorbed through a color filter by increasing the light absorption coefficient of a fluorescent substance layer and of maximizing energy efficiency by increasing the intensity of light passing through the color filter in such a manner that light is circulated again within the fluorescent substance layer by forming an LPR layer between a color filter layer and the fluorescent substance layer.

Technical objects to be achieved by the present invention are not limited to the aforementioned object, and those skilled in the art to which the present invention pertains may evidently understand other technical objects from the following description.

A display device according to an aspect of the present invention includes a light-emitting unit configured to generate light, a color filter configured to transmit light which belongs to the generated light and which corresponds to a first wavelength range of the first wavelength range and a second wavelength range, a fluorescent substance layer interposed between the light-emitting unit and the color filter and configured to emit light of the first wavelength range by absorbing light of the second wavelength range, and a reflection layer configured to reflect light of the second wavelength range transmitted without being absorbed by the fluorescent substance layer so that the reflected light is absorbed again by the fluorescent substance layer.

In some embodiments, the first wavelength range may include a wavelength range implementing one of red (R), green (G) and blue (B), and the second wavelength range may include a wavelength range implementing the other of the red (R), green (G) and blue (B).

Alternatively, in some embodiments, the first wavelength range may include a wavelength range implementing one of red (R) and yellow (Y), and the second wavelength range may include a wavelength range implementing the other of the red (R) and yellow (Y).

In this case, the fluorescent substance layer may include quantum dots.

Furthermore, the reflection layer may include a distributed Bragg reflector (DBR) or a long pass reflector (LPR). In some embodiments, the LPR structure may have a structure in which substances having different refractive indices have been stacked.

In some embodiments, the reflection layer may be formed to surround one side of the fluorescent substance layer.

Alternatively, in some embodiments, the reflection layer may be interposed between the fluorescent substance layer and the color filter.

Alternatively, the reflection layer may be formed on the side opposite the side of the light-emitting unit with the fluorescent substance layer interposed between the reflection layer and the light-emitting unit so that the light of the second wavelength range reflected by the reflection layer is reflected again by a surface of the light-emitting unit and circulated within the fluorescent substance layer.

In this case, the light-emitting unit may be white OLED (WOLED).

Furthermore, a display device according to another aspect of the present invention includes a first color filter configured to transmit light of a first wavelength range, a second color filter configured to transmit light of a second wavelength range, a third color filter configured to transmit light of a third wavelength range, a light-emitting unit configured to radiate light to the first color filter, the second color filter and the third color filter, a first fluorescent substance layer interposed between the light-emitting unit and the first color filter and configured to absorb light of the second and the third wavelength ranges and to emit light of the first wavelength range, a second fluorescent substance layer interposed between the light-emitting unit and the second color filter and configured to absorb light of the third wavelength range and to emit light of the second wavelength range, a first reflection layer interposed between the first color filter and the first fluorescent substance layer and configured to reflect the light of the second and the third wavelength ranges passing through the first fluorescent substance layer so that the reflected light is absorbed by the first fluorescent substance layer again, and a second reflection layer interposed between the second color filter and the second fluorescent substance layer and configured to reflect the light of the third wavelength range passing through the second fluorescent substance layer so that the reflected light is absorbed by the second fluorescent substance layer again.

In this case, the first color filter, the second color filter and the third color filter may be formed on a substrate in such a way as to be patterned on the substrate.

Furthermore, the first fluorescent substance layer and the second fluorescent substance layer may be formed on a substrate in such a way as to be patterned on the substrate.

Furthermore, the first reflection layer and the second reflection layer may be formed on a substrate in such a way as to be patterned on the substrate.

The reflection layer may include a distributed Bragg reflector (DBR) or a long pass reflector (LPR), and the fluorescent substance layer may include quantum dots.

Furthermore, a method for manufacturing a display panel according to yet another aspect of the present invention may include a fluorescent substance stacking step for patterning a fluorescent substance layer on a substrate using a lithography method, an LPR stacking step for patterning an LPR structure layer on the fluorescent substance layer using a deposition method, and a color filter stacking step for patterning a color filter layer on the LPR structure layer using a lithography method.

An encapsulation step may be performed between the fluorescent substance stacking step and the LPR stacking step and between the LPR stacking step and the color filter stacking step.

### BRIEF DESCRIPTION OF THE DRAWINGS

FIG. 1 schematically shows the configuration of a display device according to an embodiment of the present invention.

FIG. 2 shows an LPR structure.

FIG. 3 schematically shows wavelength ranges transmitted by an LPR and a color filter.

FIG. 4 shows a method for manufacturing the display panel according to an embodiment of the present invention.

### DETAILED DESCRIPTION

Embodiments of the present invention are described in detail with reference to the accompanying drawings.

It is to be noted that in assigning reference numerals to elements in the drawings, the same reference numerals denote the same elements throughout the drawings even in cases where the elements are shown in different drawings. Furthermore, in describing the embodiments of the present invention, a detailed description of the known functions and constitutions will be omitted if it is deemed to make the gist of the present invention unnecessarily vague.

Furthermore, the size or shape of the elements shown in the drawings may have been enlarged for the clarity of a description and for convenience sake. Furthermore, terms specifically defined by taking into consideration the configuration and operation of the present invention are merely for illustrating the embodiments of the present invention and do not limit the range of right of the present invention

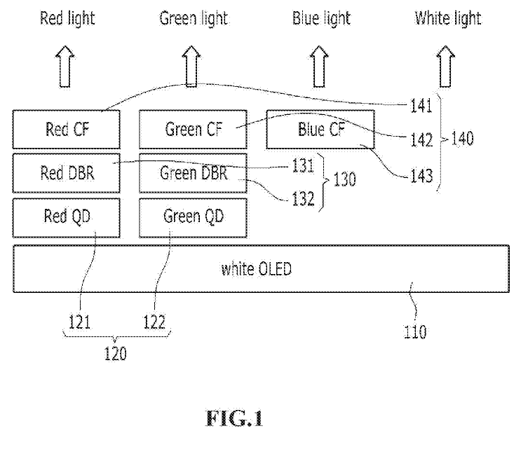

FIG. 1 schematically shows the configuration of a display device according to an embodiment of the present invention.

The display device 100 according to an embodiment of the present invention is configured to include a light-emitting unit 110 configured to generate light, a color filter 140 configured to transmit light which belongs to the generated light and which corresponds to a first wavelength range of the first wavelength range and a second wavelength range, a fluorescent substance layer 120 interposed between the light-emitting unit 110 and the color filler 140 and configured to emit light of the first wavelength range by absorbing light of the second wavelength range, and a reflection layer 130 configured to reflect light of the second wavelength range transmitted without being absorbed by the fluorescent substance layer 120 so that the reflected light is absorbed again by the fluorescent substance layer 120.

In this case, the light-emitting unit 110 has a wide meaning including various devices and apparatuses that emit light. For example, the light-emitting unit 110 may be the backlight unit of the display device 100. The light-emitting unit 110 may be a device separated from a display panel including the color filter 140, the fluorescent substance layer 120 and the reflection layer 130 or may be integrated with the display panel. In this case, light may include white light and blue light, for example, but is not limited thereto.

The light-emitting unit 110 radiates light toward all of the plurality of color filters 140 that transmits light of a specific wavelength range.

The color filter 140 functions to receive light from the light-emitting unit 110, to discard light of a predetermined wavelength range by absorbing it, and to implement a color by transmitting light of another predetermined wavelength range. The color filters 140 having different wavelength ranges in which light is absorbed and transmitted may also be used. RGB colors of the display device 100 may be implemented by such a function of the color filter 140.

The fluorescent substance layer 120 functions to emit light of another predetermined wavelength range by absorbing light of a predetermined wavelength range. In this case, the light of the wavelength range absorbed by the fluorescent substance layer 120 means the light of a wavelength range that is absorbed and discarded by the color filter 140. That is, the light of a wavelength range absorbed and discarded by the color filter 140 is absorbed by the fluorescent substance layer 120, which emits light of a wavelength range transmitted by the color filter 140. Accordingly, the intensity of light passing through the color filter 140 can be further increased, energy consumption can be reduced because absorbed and discarded light is reduced, and color sense reproducibility is enhanced.

The fluorescent substance layers 120 having different wavelength ranges in which light is absorbed and transmitted may also be used. The fluorescent substance lasers 120 may be formed by patterning fluorescent substances on a substrate using a lithography method. This is described later.

The fluorescent substance layer 120 may be disposed close to a surface of the light-emitting unit 110. In some embodiments, the fluorescent substance layer 120 may include a quantum dot substance, but the present invention is not limited to the quantum dot substance. Any substance capable of receiving light of a specific wavelength range and emitting light of another wavelength range may be applied to the fluorescent substance layer 120.

Quantum dots may mean a single substance including the II-VI group (e.g., CdSe, CdS, CdTe, ZnSe and ZnS) and the III-V group (e.g., InP, GaAs, GaP and GaN) or a substance having a core/shell structure, but is not limited thereto.

In general, an yttrium aluminum garnet (YAG)-based fluorescent substance has a thickness of micrometers (10̂-6 m) (1-100 μm). Accordingly, the YAG-based fluorescent substance is not suitable for a display that requires a thin thickness. In an embodiment of the present invention, however, the YAG-based fluorescent substance may be used by reducing the thickness of the fluorescent substance as thin as possible.

Quantum dots may be used because they can be suitably processed for the display device according to an embodiment of the present invention.

The thickness of a film may be processed 10 micrometers or less using quantum dots. In some cases, the film may be increased to a thickness of about 50 micrometers.

Light of the second wavelength range may have greater energy than light of the first wavelength range. That is, the first wavelength range may be greater than the second wavelength range.

In some embodiments, the first wavelength range may be a wavelength range that implements one of red (R), green (G) and blue (B), and the second wavelength range may be a wavelength range that implements the other of red (R), green (R) and blue (B). For example, if the first wavelength range is a wavelength range implementing red (R), the second wavelength range may be a wavelength range implementing green (G) or/and blue (B). If the first wavelength range is a wavelength range implementing green (G), the second wavelength range may be a wavelength range implementing blue (B).

In another embodiment, the first wavelength range may be a wavelength range implementing yellow (Y), and the second wavelength range may be a wavelength range implementing red (R).

In general, the absorption coefficient of the fluorescent substance layer 120 is not high. Accordingly, if the fluorescent substance layer 120 is formed between the color filter 140 and the light-emitting unit 110, most of light emitted from the light-emitting unit 110 reaches the color filter 140 without being absorbed by the fluorescent substance layer 120. As a result, most of the light is absorbed and discarded by the color filter 140. Accordingly, if the fluorescent substance layer 120 is disposed between the color filter 140 and the light-emitting unit 110, energy consumption is not significantly improved because a large amount of energy is absorbed and discarded although the fluorescent substance layer 120 has been formed.

The reflection layer 130 may function to transmit light of a predetermined wavelength range and to reflect light of another predetermined wavelength range. That is, the reflection layer 130 may reflect light that must be absorbed by the fluorescent substance layer 120, but passes through the fluorescent substance layer 120 without being absorbed by the fluorescent substance layer 120 so that the light is circulated again within the fluorescent substance layer 120. That is, the reflection layer 130 reflects light transmitted by the fluorescent substance layer 120 without being absorbed by the fluorescent substance layer 120 so that the transmitted light is circulated within the fluorescent substance layer 120 and absorbed by the fluorescent substance layer 120 again. Such pieces of light continue to be reflected toward the inside of the fluorescent substance layer 120. As a result, most of the pieces of light are absorbed again. Accordingly, corresponding light is converted into light of a wavelength range corresponding to a color to be implemented through the color filter 140 and emitted. As a result, the intensity of light externally output through the color filter 140 is further increased, thereby having excellent color reproducibility.

In some embodiments, the reflection layer 130 may be formed to surround a surface that belongs to the surface of the fluorescent substance layer 120 and through which light passes. In this case, light emitted from the fluorescent substance layer 120 can be effectively reflected.

In another embodiment, the reflection layer 130 may be formed on the side opposite the side of the light-emitting unit 110 with the fluorescent substance layer 120 interposed therebetween so that light of the second wavelength range emitted from the reflection layer 130 is reflected by the surface of the light-emitting unit 110 again and circulated within the fluorescent substance layer 120.

The surface of the light-emitting unit 110 has a high reflectance. The light-emitting unit 110 and the reflection layer 130 are configured to be disposed on one surface and the other surface of the fluorescent substance layer 120, respectively, with the fluorescent substance layer 120 interposed therebetween. According to such a configuration, part of light emitted from the light-emitting unit 110 is absorbed by the fluorescent substance layer 120. Light that must be absorbed by the fluorescent substance layer 120, but is not absorbed is reflected by the reflection layer 130 and is absorbed by the fluorescent substance layer 120 again. Furthermore, the light passing through the fluorescent substance layer 120 without being absorbed by the fluorescent substance layer 120 again is reflected by the light-emitting unit 110 again and is absorbed by the fluorescent substance layer 120 again. As a result, all of types of light that need to be absorbed by the fluorescent substance layer 120 are converted into light that needs to be externally output and are then output to the outside.

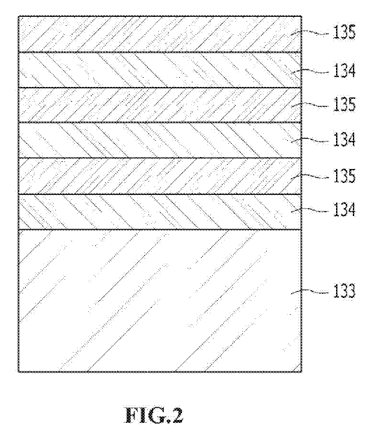

FIG. 2 shows the structure of a long pass reflector (LPR).

In some embodiments, the reflection layer 130 may be a distributed Bragg reflector (DBR) or a long pass reflector (LPR). In this case, the LPR may mean a structure in which a plurality of different substances 134 and 135 having different refractive indices has been stacked.

The LPR structure may be formed by sequentially stacking the substances 134 and 135 having different refractive indices on a substrate 133 using a method, such as sputtering. The LPR structure may be designed to transmit light of a required wavelength range and to reflect light of another predetermined wavelength range by setting a refractive index, the thickness of a substance and so on.

In some embodiments, the DBR or LPR may have a structure in which substances having different refractive indices, for example, SiO2 and TiO2 are alternately stacked.

Furthermore, the display device 100 according to another embodiment of the present invention is configured to include a first color filter 141 configured to transmit light of the first wavelength range, a second color filter 142 configured to transmit light of the second wavelength range, a third color filter 143 configured to transmit light of the third wavelength range, a light-emitting unit 110 configured to radiate light to the first color filter 141, the second color filter 142 and the third color filter 143, a first fluorescent substance layer 121 interposed between the light-emitting unit 110 and the first color filter 141 and configured to absorb light of the second and the third wavelength ranges and to emit light of the first wavelength range, a second fluorescent substance layer 122 interposed between the light-emitting unit 110 and the second color filter 142 and configured to absorb light of the third wavelength range and to emit light of the second wavelength range, a first reflection layer 131 interposed between the first color filter 141 and the first fluorescent substance layer 121 and configured to reflect the light of the second and the third wavelength ranges passing through the first fluorescent substance layer 121 so that the reflected light is absorbed by the first fluorescent substance layer 121 again, and a second reflection layer 132 interposed between the second color filter 142 and the second fluorescent substance layer 122 and configured to reflect the light of the third wavelength range passing through the second fluorescent substance layer 122 so that the reflected light is absorbed by the second fluorescent substance layer 122 again.

In some embodiments, the first fluorescent substance layer 121 and the second fluorescent substance layer 122 may be formed in such a way as to pattern them on the substrate. Furthermore, the first reflection layer 131 and the second reflection layer 132 may also be formed in such a way as to pattern them on the substrate.

Furthermore, in some embodiments, the reflection layer 130 may be formed of a distributed Bragg reflector (DBR) or a long pass reflector (LPR). The fluorescent substance layer 120 may be formed of quantum dots.

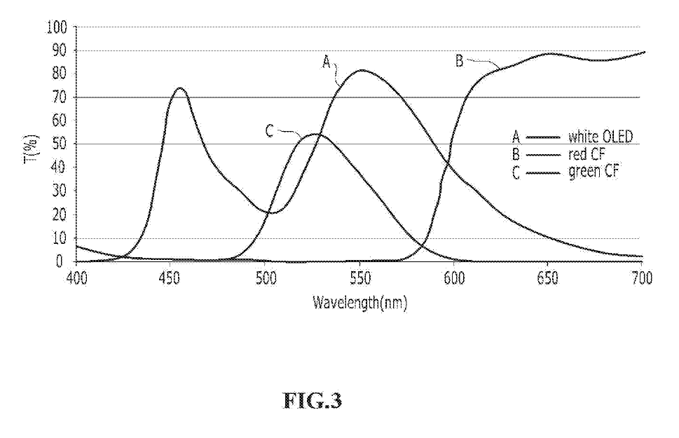

FIG. 3 schematically shows wavelength ranges transmitted by the LPR and the color filter.

For example, the light-emitting unit 110 may be an OLED emitting white light, for example. The first color filter 141, the second color filter 142 and the third color filter 143 may be an R color filter, a G color filter and a B color filter, respectively.

The light-emitting unit 110 may have a wavelength range A including all of red, green and blue. The first wavelength range B may mean a wavelength range of red light, the second wavelength range C may mean a wavelength range of green light and the third wavelength range may mean a wavelength range of blue light (not shown).

That is, the first color filter 141 may be a filter that transmits a wavelength range of red light and absorbs wavelength ranges of green and blue light. The second color filter 142 may be a filter that transmits a wavelength range of green light and absorbs wavelength ranges of red and blue light. The third color filter 143 may be a filter that transmits a wavelength range of blue light and absorbs wavelength ranges of green and red light.

Furthermore, for example, the first fluorescent substance layer 121 may be a fluorescent substance that absorbs green and blue light and emits red light. The second fluorescent substance layer 122 may be a fluorescent substance that absorbs blue light and emits green light.

Furthermore, the first reflection layer 131 may transmit red light and reflect green and blue light. The second reflection layer 132 may transmit green and red light and reflect blue light.

In the example described above with reference to FIG. 1, a process of transmitting light is described. Red light of light emitted by the light-emitting unit 110 sequentially passes through the first fluorescent substance layer 121, the first reflection layer 131 and the first color filter 141 and is emitted to the outside.

In contrast, green light and blue light are partially absorbed by the first fluorescent substance layer 121. The absorbed energy is converted into red light and then emitted to the outside through the first reflection layer 131 and the first color filter 141.

The remaining light that belongs to the green light and the blue light and that is not absorbed by the first fluorescent substance layer 121 travels to the first reflection layer 131 through the first fluorescent substance layer 121, but is reflected by the first reflection layer 131 and returned to the first fluorescent substance layer 121. The reflected light is absorbed by the first fluorescent substance layer 121 again, converted into red light, and then emitted to the outside through the first reflection layer 131 and the first color filter 141.

Furthermore, light that belongs to the light reflected by the first reflection layer 131 and returned to the first fluorescent substance layer 121 and that is not absorbed by the first fluorescent substance layer 121 again passes through the first fluorescent substance layer 121 ad travels to the light-emitting unit 110 on the other side. However, the light is reflected by a surface of the light-emitting unit 110 because the surface of the light-emitting unit 110 has a high reflectance and is then returned and absorbed by the first fluorescent substance layer 121.

As described above, light not directly absorbed by the first fluorescent substance layer 121 is reflected by the first reflection layer 131 and the light-emitting unit 110 and circulated within the first fluorescent substance layer 121. As a result, the entire circulating light is absorbed by the first fluorescent substance laser 121, converted into red light, and then emitted to the outside through the first reflection layer 131 and the first color filter 141. There is an advantage in that color reproducibility is improved because the intensity of red light that emits as described above is increased.

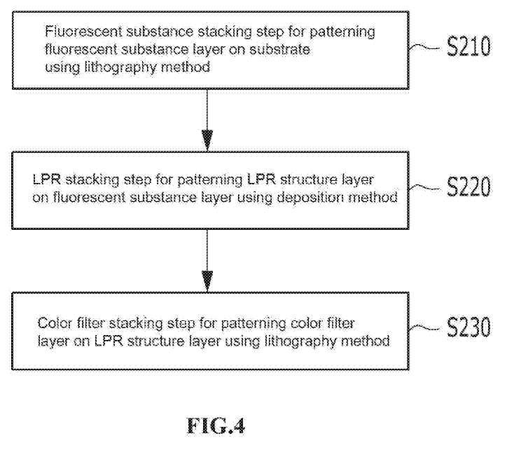

FIG. 4 shows a method for manufacturing the display panel according to an embodiment of the present invention.

The method for manufacturing a display panel according to yet another embodiment of the present invention may include a color filter stacking step S210 for patterning the laser of the color filter 140 on the substrate using a lithography method, an LPR stacking step S220 for patterning the LPR structure layer on the layer of the color filter 140 using a deposition method, and a fluorescent substance stacking step S230 for patterning the fluorescent substance layer 120 on the LPR structure layer using a lithography method.

In this case, an encapsulation step may be performed between the color filter stacking step S210 and the LPR stacking step S220 and between the LPR stacking step S220 and the fluorescent substance stacking step S230.

A method for patterning quantum dots may be a lithography method. More specifically, the method for patterning quantum dots may include (i) dispersing quantum dots in a photoresist substance, (ii) coating a film using spin coating, slit coating and dip coating, (iii) supplying thermal energy through a pre-baking process, (iv) supplying light energy through an exposure process, (v) supplying thermal energy again through a post-exposure baking process, (vi) performing a development process, (vii) performing a rinse process and (viii) supplying thermal energy through a hard-baking process. In this case, an etching or lift-off process may be added depending on a required pattern. A method for patterning quantum dots is not limited to the aforementioned method.

A method for patterning the DBR or LPR may be performed by deposition, that is, a deposition method, in some embodiments. The deposition method may be performed by a technique, such as sputtering, evaporation, e-beam evaporation, or ion-implantation. In this case, an etching or lift-off process may be added depending on a required pattern.

In accordance with an embodiment of the present invention, the LPR layer is interposed between the color filter layer and the fluorescent substance layer so that light is circulated within the fluorescent substance layer again. Accordingly, there is provided the display panel capable of reducing the amount of light absorbed through the color filter by increasing the light absorption coefficient of the fluorescent substance layer and of maximizing energy efficiency by increasing the intensity of light passing through the color filter.

In addition, the effects of the present invention have various effects, such as excellent generality, in some embodiments, and such effects may be evidently checked in the descriptive part of the embodiments to be described later.

While some exemplary embodiments of the present invention have been described with reference to the accompanying drawings, those skilled in the art may change and modify the present invention in various ways without departing from the essential characteristic of the present invention.

The disclosed embodiments should not be construed as limiting the technical spirit of the present invention, but should be construed as illustrating the technical spirit of the present indention. The scope of the technical spirit of the present invention is not restricted by the embodiments.

The range of protection of the present invention should be interpreted based on the following appended claims. Accordingly, the present invention should be construed as covering all modifications or variations derived from the meaning and scope of the appended claims and their equivalents.

What is claimed is:

1. A display device, comprising:
a light-emitting unit configured to generate light;
a color filter configured to transmit light which belongs to the generated light and which corresponds to a first wavelength range of the first wavelength range and a second wavelength range;
a fluorescent substance layer interposed between the light-emitting unit and the color filter and configured to emit light of the first wavelength range by absorbing light of the second wavelength range; and
a reflection layer configured to reflect light of the second wavelength range transmitted without being absorbed by the fluorescent substance layer so that the reflected light is absorbed again by the fluorescent substance layer.

2. The display device of claim 1, wherein:
the first wavelength range comprises a wavelength range implementing one of red (R), green (G) and blue (B) and the second wavelength range comprises a wavelength range implementing the other of the red (R), green (G) and blue (B), or
the first wavelength range comprises a wavelength range implementing one of red (R) and yellow (Y) and the second wavelength range comprises a wavelength range implementing the other of the red (R) and yellow (Y).

3. The display device of claim 1, wherein the fluorescent substance layer comprises quantum dots.

4. The display device of claim 1, wherein the reflection layer composes a distributed Bragg reflector (DBR) or a long pass reflector (LPR).

5. The display device of claim 1, wherein the reflection layer is interposed between the fluorescent substance layer and the color filter.

6. The display device of claim 1, wherein the reflection layer is formed on a side opposite a side of the light-emitting unit with the fluorescent substance layer interposed between the reflection layer and the light-emitting unit so that the light of the second wavelength range reflected by the reflection layer is reflected again by a surface of the light-emitting unit and circulated within the fluorescent substance layer.

7. The display device of claim 1, wherein the light generated by the light-emitting unit comprises white light.

8. A display device, comprising:
a first color filter configured to transmit light of a first wavelength range;
a second color filter configured to transmit light of a second wavelength range;
a third color filter configured to transmit light of a third wavelength range;
a light-emitting unit configured to radiate light to the first color filter, the second color filter and the third color filter;
a first fluorescent substance layer interposed between the light-emitting unit and the first color filter and configured to absorb light of the second and the third wavelength ranges and to emit light of the first wavelength range;
a second fluorescent substance layer interposed between the light-emitting unit and the second color filter and configured to absorb light of the third wavelength range and to emit light of the second wavelength range;
a first reflection layer interposed between the first color filter and the first fluorescent substance layer and configured to reflect the light of the second and the third wavelength ranges passing through the first fluorescent substance layer so that the reflected light is absorbed by the first fluorescent substance layer again; and
a second reflection layer interposed between the second color filter and the second fluorescent substance layer and configured to reflect the light of the third wavelength range passing through the second fluorescent substance layer so that the reflected light is absorbed by the second fluorescent substance layer again.

9. The display device of claim 8, wherein the first color filler, the second color filter and the third color filter are formed on a substrate in such a way as to be patterned on the substrate.

10. The display device of claim 8, wherein the first fluorescent substance layer and the second fluorescent substance layer are formed on a substrate in such a way as to be patterned on the substrate.

11. The display device of claim 8, wherein the first reflection layer and the second reflection layer are formed on a substrate in such a way as to be patterned on the substrate.

12. The display device of claim 8, wherein:
the reflection layer comprises a distributed Bragg reflector (DBR) or a long pass reflector (LPR), and
the fluorescent substance layer comprises quantum dots.

13. A method for manufacturing a display panel, comprising:
a fluorescent substance stacking step for patterning a fluorescent substance layer on a substrate using a lithography method;
an LPR stacking step for patterning an LPR structure layer on the fluorescent substance layer using a deposition method; and
a color filter stacking step for patterning a color filter layer on the LPR structure layer using a lithography method.

14. The method of claim 13, wherein an encapsulation step is performed between the fluorescent substance stacking step and the LPR stacking step and between the LPR stacking step and the color filter stacking step.
